(19) United States
(12) Patent Application Publication
(10) Pub. No.: US 2023/0339001 A1
(43) Pub. Date: Oct. 26, 2023

(54) METHOD FOR RECYCLING SOLAR PANEL, AND DEVICE FOR RECYCLING SOLAR PANEL

(71) Applicant: SINTOKOGIO, LTD., Nagoya-shi, Aichi (JP)

(72) Inventor: Takeru MIYAKO, Nagoya-shi (JP)

(73) Assignee: SINTOKOGIO, LTD., Nagoya-shi, Aichi (JP)

(21) Appl. No.: 18/016,515

(22) PCT Filed: Sep. 27, 2021
(86) PCT No.: PCT/JP2021/035355

§ 371 Date: Jan. 17, 2023

(30) Foreign Application Priority Data
Sep. 28, 2020 (JP) 2020-161738

(51) Int. Cl. B09B 3/35

(52) U.S. Cl. CPC B09B 3/35; B09B 2101/15

(57) ABSTRACT

A method and device for recycling a solar panel with which a cover glass is separated efficiently from the solar panel, the method including: [1] ascertaining feature quantities of the solar panel, including the thickness of a cover glass and the hardness of the cover glass; [2] setting a process condition on the basis of the feature quantities of the solar panel; and [3] separating the cover glass from the solar panel by imparting an impact force to the solar panel by means of a processing medium, on the basis of the process condition.

### TECHNICAL FIELD

The present invention relates to a method for recycling solar panels, and a device for recycling solar panels.

### BACKGROUND

Solar panel-based photovoltaic systems have attracted attention from the viewpoint of renewable energy that does not emit greenhouse gases and the introduction of such installations is rapidly increasing. Solar panels are set to last approximately 25 to 30 years, at which time it is anticipated that a large amount of waste including solar panels will be generated. For example, according to calculations by the Ministry of the Environment in Japan, approximately 800,000 tons of waste is anticipated to be emitted in 2039. Accordingly, there is an urgent need to establish a system that recycles and recirculates solar panels.

FIG. 3 schematically illustrates a cross-sectional view of one portion of a common solar panel. The solar panel 100 is a plate-like structure in which solar cells 102a comprising electrodes 102b and connected by wirings 102c are sealed with a cover glass 101, an encapsulant 102d (such as ethylene-vinyl acetate (EVA)), and a backsheet 103, with an outer frame 104a (such as aluminum) fitted via a sealing material 104b. The layer 102 in which solar cells 102a are encapsulated by the encapsulant 102d is hereinafter referred to as a power generating layer.

In the past, solar panels were processed by crushing the solar panels themselves due to difficulty in separating the cover glass from the solar panel. However, if the cover glass can be separated, the cover glass can be recycled as glass and the recovery of valuable resources such as silver and aluminum can be expected from cell members such as the power generating layer. In other words, the establishment of technology that can efficiently separate the cover glass from a solar panel is desired.

Patent Document 1 discloses a method for recycling solar panels comprising: a “disassembling step” for removing a frame, output cables, a terminal box, and the like from a solar cell panel to be recycled; a “heating and softening step” for subjecting the solar panel to an annealing process to decrease the adhesion between a cover glass and an encapsulant; a “first detaching step” for detaching a portion of the cover glass; a “second detaching step” for completely detaching the cover glass; and a “recovering step” for recovering the cover glass that was detached.

### CITATION LIST

### Patent Literature

Patent Document 1: JP 2015-110201 A

### SUMMARY OF INVENTION

### Technical Problem

In the “heating and softening step” mentioned above in Patent Document 1, the solar panel is heated and then slowly cooled to room temperature. According to the patent document, the heating time takes 60 to 90 minutes. In addition, in the “first detaching step” as well, a heating process for softening the encapsulant is performed. Accordingly, the establishment of a new recycling method is desired from the viewpoint of processing time and the like.

The present invention was made in view of the circumstances discussed above, and a problem to be solved by the present invention is to provide a method and device for recycling solar panels by efficiently separating cover glasses from solar panels.

### Solution to Problem

One aspect of the present invention is a method for recycling solar panels. The recycling method comprises the steps of:
(1) ascertaining a feature amount of a solar panel including the thickness of a cover glass and the hardness of the cover glass;
(2) setting a processing condition based on the feature amount of the solar panel; and
(3) based on the processing condition, applying an impact force to the solar panel by means of processing media to separate the cover glass (member covering a surface of the solar panel) from the solar panel.

According to one aspect of the present invention, processing conditions are set based on the feature amounts of solar panels. Thus, it is possible to appropriately separate only the cover glass by means of processing media without breaking the power generating layer under the cover glass.

In one embodiment of the present invention, the processing media may be particles having a diameter of 0.6 to 3.0 mm. Moreover, separation of a cover glass from a solar panel comprises the steps of:
(1) causing the processing media to collide with the solar panel to form a crack in the cover glass;
(2) further causing the processing media to collide with the solar panel to grow the crack; and
(3) further causing the processing media to collide with the solar panel to remove the cover glass from the solar panel in particulate form.

The cover glass can be separated by causing the processing media in particulate form to repeatedly collide with the solar panel to gradually grow cracks in the cover glass and, by means of the collision force thereof, decreasing the adhesive force between the power generating layer and the cover glass. In other words, it is possible to reduce damage to the power generating layer when separating the cover glass.

In one embodiment of the present invention, separation of broken pieces of the cover glass from particles including the processing media that was used for separation of the cover glass and broken pieces of the cover glass that was separated may be included.

Because broken pieces of cover glasses are appropriately separated, broken pieces of the cover glass can be recovered and recycled.

In one embodiment of the present invention, the processing condition may comprise the energy when processing media collides with the solar panel. In addition, the Vickers hardness of the processing media is 350 to 550 HV and the energy when colliding with the solar panel may be 1.0×10⁻³ to 5.3×10⁻¹ J. In addition, the Vickers hardness of the processing media is 60 to 150 HV and the energy when colliding with the solar panel may be 9.0×10⁻⁴ to 5.0×10⁻¹ J.

It is possible to appropriately control the conditions of processing for separating the cover glass.

Another aspect of the present invention is a device for recycling solar panels. The device includes an impact force applying mechanism, an input portion, and a control portion. The impact force applying mechanism is a mechanism that applies a collision force to the solar panel by means of processing media. The input portion inputs a feature amount of the solar panel (including the thickness of the cover glass and the hardness of the cover glass). The control portion controls the impact force applying mechanism. In addition, the control portion sets processing conditions based on the feature amounts of the solar panel. Moreover, the control portion controls the impact force applying mechanism based on the processing conditions that were set to separate the cover glass (member covering a surface of the solar panel) from the solar panel.

According to another aspect of the present invention, the control portion sets processing conditions based on the feature amounts of the solar panel and the impact force applying mechanism processes the solar panel with the processing conditions that were set. Thus, it is possible to more appropriately separate only the cover glass by means of the processing media without breaking the power generating layer under the cover glass.

In one embodiment of the present invention, processing media that is multiple particles having a diameter of 0.6 to 3.0 mm may be projected toward the solar panel. The repeated impact of the processing media causes the cracks that have formed in the cover glass to grow, eventually causing the cover glass to be removed in particulate form. Accordingly, the cover glass can be separated without damaging the power generating layer.

In one embodiment of the present invention, a first separating mechanism and a second separating mechanism may be provided. Here, the first separating mechanism performs separation into “broken pieces of the cover glass that was separated from the solar panel and the processing media” and “the solar panel from which the cover glass was separated”. In addition, the second separating mechanism separates the “broken pieces of the cover glass” from the “broken pieces of the cover glass and the processing media” that were separated by the first separating mechanism.

Because mechanisms for appropriately separating broken pieces of cover glasses are provided, broken pieces of the cover glass can be recovered and recycled.

### Effects of Invention

According to the present invention, it is possible to provide a method for recycling solar panels by separating the cover glasses of solar panels and a device for recycling solar panels.

### BRIEF DESCRIPTION OF DRAWINGS

FIG. 1 is a side view schematically illustrating a cover glass processing device according to an embodiment of the present invention.

FIG. 2 is a cross-sectional view taken along line A-A in FIG. 1.

FIG. 3 is a cross-sectional view of a portion of a solar panel that is to be processed in an embodiment of the present invention.

### DESCRIPTION OF EMBODIMENTS

### Embodiments

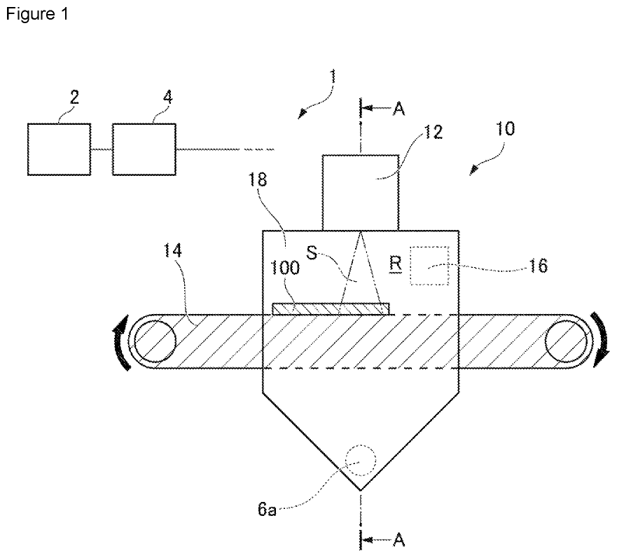

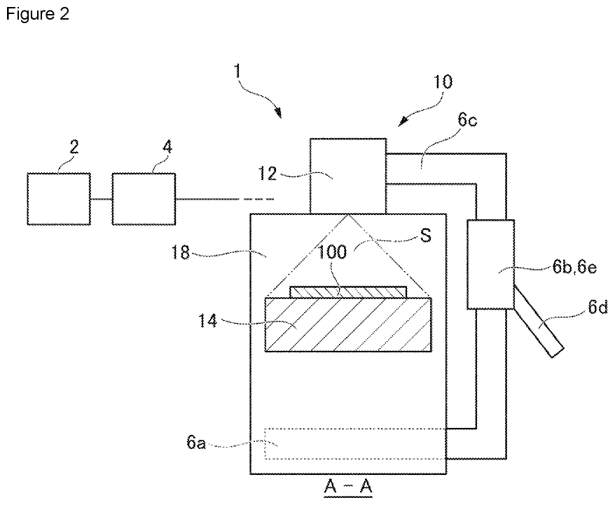

Embodiments of the present invention will be described below with reference to the drawings. FIG. 1 is a side view schematically illustrating a device (cover glass processing device) for recycling a solar panel according to an embodiment of the present invention. FIG. 2 is a cross-sectional view taken along line A-A in FIG. 1.

As illustrated in FIGS. 1 and 2, the solar panel cover glass processing device 1 comprises an impact force applying mechanism 12, a cabinet 18, a conveying mechanism 14, a first separating mechanism 16, a second separating mechanism 6b, a third separating mechanism 6e, an input portion 2, and a control portion 4.

The control portion 4 performs various control including operations and settings of processing conditions of the cover glass processing device 1 discussed below. As the control portion 4, a control portion that can control the operations of the cover glass processing device 1 may be employed, including for example a motion controller such as a programmable logic controller (PLC) or a digital signal processor (DSP), or various types of computation devices such as a personal computer (PC). As the input portion 2, an input portion that makes it possible to input settings for the cover glass processing device 1 and the like in conjunction with an image display device may be employed, including for example a keyboard, a mouse, or a touch panel.

The impact force applying mechanism 12 continuously projects processing media S in particulate form. The impact force applying mechanism 12 comprises a drive source and a projection mechanism. An electric motor, for example, is used as the drive source. In addition, an impeller that is rotatably driven by the drive source may be used as the projection mechanism. In the present embodiment, the impact force applying mechanism 12 has an impeller connected to a motor and is configured so as to feed the processing media S to the impeller and utilize the centrifugal force of the impeller rotating at high speed to project the processing media S toward the object to be processed (solar panel 100).

As another configuration of the impact force applying mechanism 12, a system in which the processing media S is ejected together with compressed air can be used. In this case, the impact force applying mechanism 12 may be configured as a mechanism that sucks in processing media by means of negative pressure generated inside a nozzle and ejects the processing media together with compressed air. In addition, the impact force applying mechanism 12 may be configured as a mechanism that pressurizes a pressurized container in which the processing media S is housed by means of compressed air and feeds the processing media S into airflow flowing toward a nozzle S to eject the processing media S together with the compressed air from the nozzle.

As yet another configuration of the impact force applying mechanism 12, a method in which processing media is ejected together with a liquid and compressed air can be used.

The cabinet 18 covers an area where the processing media S is projected and the cover glass 101 is separated, and defines a processing chamber R therein.

The conveying mechanism 14 conveys the solar panel 100 to the area where the processing media S is projected and also carries the solar panel 100 from which the cover glass 101 was removed outside of the cabinet 18. As the conveying mechanism 14, a belt conveyor, a vibrating feeder, a chain conveyor, a roller conveyor, and the like can be used. In the present embodiment, a belt conveyor is used.

The first separating mechanism 16 is a mechanism that performs separation into “the cover glass 101 that was separated from the power generating layer 102 in the solar panel 100, the processing media S, and other particles (resulting from the separation process)” and “the power generating layer 102”. As the first separating mechanism 16 in the present embodiment, a mechanism that performs separation by means of external force such as a scraper, a brush, or a blower using compressed air was used.

As another configuration of the first separating mechanism 16, a vibrating feeder may be used as the conveying mechanism 14 and a screen may be used for the conveying portion where the solar panel 100 is placed. In this case, the conveying mechanism 14 can also serve as the first separating mechanism 16.

The third separating mechanism 6e is a mechanism that separates and recovers the “other particles” from “the cover glass 101, the processing media S, and other particles” that were separated by the first separating mechanism. The third separating mechanism 6e may be configured to perform sorting by means of wind force. The third separating mechanism 6e can be omitted as needed, such as when the amount of “other particles” generated is small.

The second separating mechanism 6b is a mechanism that separates the “cover glass 101” and the “processing media S” from “the cover glass 101, the processing media S, and other particles” that were separated by the first separating mechanism. The “cover glass 101 and the processing media S” that were separated by the third separating mechanism are separated into the “processing media S” and the “cover glass 101” by the second separating mechanism 6b. The second separating mechanism 6b can be selected from a sieve, a wind force sorting device, a magnetic sorting device, and the like. In addition, these can also be used in combination.

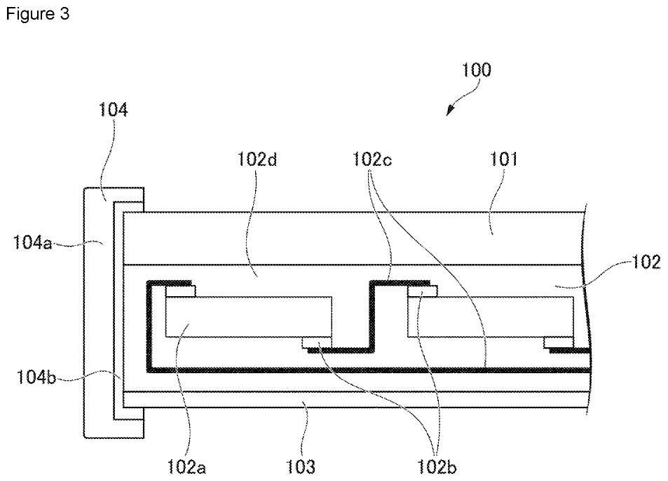

Next, the operations of the solar panel cover glass processing device 1 configured as described above will be described. The frame portion 104 comprising an aluminum outer frame 104a and a sealing material 104b in FIG. 3 is removed from the solar panel 100 to be processed in the present embodiment, and then the solar panel 100 is supplied to a separating device 1 as only a laminate comprising a cover glass 101, a power generating layer 102, and a backsheet 103.

(1) First, an operator inputs feature amounts of the solar panel 100 to be processed into the input portion 2. The feature amounts include the thickness of the cover glass and the hardness of the cover glass.

(2) The control portion 4 sets processing conditions based on the feature amounts of the solar panel 100 that were inputted. Based on the processing conditions that were set, signals that control mechanisms including the impact force applying mechanism 12 are outputted to the mechanisms.

(3) Next, the conveying mechanism 14 operates and the solar panel 100 that was placed on the conveying mechanism 14 is conveyed to a position directly below the impact force applying mechanism 12 within the cabinet 18. Then, a countless number of processing media S are continuously projected toward the solar panel 100 through the operation of the impact force applying mechanism 12. An impact force is applied to the cover glass 101 through projection of the processing media S. The cover glass 101 is separated in the following manner through the impact force.

a) At the initial stage of projection, a countless number of small cracks are formed in the cover glass 101.

b) By further continuing to project the processing media S and continuing to apply an impact force, the cracks grow in the depth direction.

c) The cracks in the cover glass 101 are in a so-called “spiderweb shape”. In other words, when cracks reach the power generating layer 102, the contact area at the interface between the cover glass 101 and the power generating layer 102 is reduced, which weakens the adhesive force. By further continuing to apply an impact force through projection in this state, the cover glass 101 is removed in particulate form. Because the cover glass is separated in the manner mentioned above by performing processing according to the processing conditions that were set in step (2) above, it is possible to suppress damage to the power generating layer 102 caused by processing.

(4) The solar panel 100 that has been processed is conveyed in the rightward direction in FIG. 1, and the cover glass 101 that was separated and the processing media S are removed by the first separating mechanism 16. The laminate comprising the power generating layer 102 and the backsheet 103 from which the processing media S was removed is further conveyed by the conveying mechanism 14 and recovered for recycling.

(5) A processing media recovering portion 6a is disposed at the lower portion of the cabinet 18. The cover glass 101, the projected processing media S, and other particles (resulting from processing) that were separated by processing media recovering portion processing are recovered by the processing media recovering portion 6a at the lower portion of the cabinet 18. The processing media recovering portion 6a is composed of a screw conveyor, a bucket elevator, or the like (not shown) (see FIG. 2).

(6) The “cover glass 101, the processing media S, and other particles” that were recovered by the processing media recovering portion 6a are transferred to the third separating mechanism 6e. The “other particles” are particles having less mass compared to the “cover glass 101 and the processing media 5”. A dust collector (not shown) is connected to the third separating mechanism 6e and the “other particles” are separated by airflow generated by the operation of the dust collector. The “other particles” that were separated are recovered in the dust collector.

(7) The “cover glass 101 and the processing media 5” that were separated by the third separating mechanism 6e are transferred to the second separating mechanism 6b. Then, the “cover glass 101 and the processing media 5” are separated into the “processing media 5” and the “cover glass 101” by means of the operation of the second separating mechanism 6b. The separated cover glass is discharged outside through a discharge pipe 6d. In addition, the separated processing media S is supplied to the impact force applying mechanism 12 by a processing media supply portion 6c and projected again.

Feature Amount of Solar Panel

The feature amounts of the solar panel 100 that are inputted into the input portion 2 above can include, in addition to the thickness of the cover glass and the hardness of the cover glass, the composition of the cover glass 101, the composition, hardness, and thickness of the encapsulant 102d, the composition, hardness, and thickness of the backsheet 103, the temperature of the solar panel 100, and the like. These feature amounts are acquired from specification information regarding the solar panel model number that can be acquired in advance. In addition, the feature amounts may be acquired by performing appropriate measurements prior to processing.

In addition to the feature amounts discussed above, the degree of degradation (the effects of salt damage and water as well as ultraviolet light and heat during use) of the sheet and the encapsulant, the degree of damage to the cover glass (for example, the cover glass is already broken or scratched), the shape of the solar panel (warpage, curvature, and the like), deposits on the cover glass (those that hinder projection, such as dirt, paint, mud, and soil), and the like may be employed as feature amounts.

Processing Conditions

The processing conditions that are set based on the feature amounts of the solar panel 100 mentioned above can include the amount of energy of the processing media S colliding with the cover glass 101 in order to separate the cover glass 101, the type, hardness, and size of the processing media, and the like.

In the present embodiment, the energy (collision energy) of the processing media S when colliding with the solar panel 100 is controlled. The energy is calculated by the control portion 4 through the formula below.

S_{E}=kGₜGₕ Equation 1

Here, S_{E} represents the collision energy, k represents an experimentally determined constant, Gₜ represents the thickness of the cover glass, and Gₕ represents the hardness of the cover glass. The collision energy S_{E} is defined as the energy immediately prior to the colliding media S colliding with the solar panel 100.

The material of the processing media S is selected from various materials including metals (for example, iron, zinc, and stainless steel), ceramics (for example, alumina, silicon carbide, and zircon), glass, resins (for example, nylon resins, melamine resins, and urea resins), and plant-derived materials (for example, walnuts and peaches). The shape of the processing media S is selected from various shapes including a spherical shape, a polygonal shape, and a cylindrical shape. For example, in the case of metal particles, spherical particles called steel shot, polygonal particles having sharp corners called grit, and cylindrical particles or cylindrical particles with rounded corners called cut wire can be selected. The material and shape may be selected, as appropriate, from various materials and shapes and employed based on the feature amounts of the solar panel 100.

Furthermore, it has been found that the relationship with the hardness of the colliding media S is important for the collision energy S_{E} discussed above. For example, the collision energy S_{E} when the Vickers hardness of the processing media is 350 to 550 HV is 1.0×10⁻³ to 5.3×10⁻¹ J. For example, the collision energy S_{E} when the Vickers hardness of the processing media is 60 to 150 HV is 9.0×10⁻⁴ to 5.0×10⁻¹ J. The Vickers hardness is a numerical value that is measured according to JIS Z 0311:2004.

As discussed above, in the present embodiment, the material, hardness, shape, collision energy, and the like of the processing media S are set based on the feature amounts of the solar panel 100, and the cover glass 101 can be efficiently separated from the solar panel 100. Specifically, when separating the cover glass 101, it is possible to suppress damage to the power generating layer 102 and recycle the cover glass 101, and also recycle the power generating layer 102. In addition, because damage to the power generating layer 102 is suppressed, it is possible to prevent impurities from becoming mixing in with the broken pieces of the cover glass 101 that was recovered. The processing conditions can be adjusted such that the size and mass of the broken pieces of the cover glass 101 are different from those of the processing media S. Thus, the processing media S and the cover glass 101 can be easily separated with a sieve or a wind sorting device in the separating mechanism 6b. Accordingly, it is possible to provide a method for efficiently separating and recycling the cover glasses of solar panels and a device for recycling solar panels.

Embodiments of the present invention have been described above, but these embodiments are examples for describing the present invention. The claims cover numerous modifications to the embodiments without departing from the scope and spirit of the present invention. Accordingly, the embodiments disclosed herein are provided for illustration purposes and should not be construed as limiting the scope of the present invention.

### REFERENCE SIGNS LIST

1 Solar panel cover glass processing device
2 Input portion
4 Control portion
12 Impact force applying mechanism
16 First separating mechanism
6b Second separating mechanism
100 Solar panel
101 Cover glass
S Processing media

1. A method for recycling a solar panel comprising:
ascertaining a feature amount of the solar panel including a thickness of a cover glass and a hardness of the cover glass;
setting a processing condition based on the feature amount of the solar panel; and
based on the processing condition, applying an impact force to the solar panel by means of processing media to separate the cover glass covering a surface of the solar panel from the solar panel.

2. The method for recycling a solar panel according to claim 1, wherein:
the processing media is multiple particles with a diameter of 0.6 to 3.0 mm; and
separation of the cover glass from the solar panel comprises:
causing the processing media to collide with the solar panel to form a crack in the cover glass;
further causing the processing media to collide with the solar panel to grow the crack; and
further causing the processing media to collide with the solar panel to remove the cover glass from the solar panel in particulate form.

3. The method for recycling a solar panel according to claim 1, comprising separating broken pieces of the cover glass from particles including the processing media that was used for separation of the cover glass and broken pieces of the cover glass that was separated.

4. The method for recycling a solar panel according to claim 1, wherein the processing condition includes an energy when the processing media collides with the solar panel.

5. The method for recycling a solar panel according to claim 4, wherein:
a Vickers hardness of the processing media is 350 to 550 HV; and
the energy when colliding with the solar panel is 1.0×10⁻³ to 5.3×10⁻¹ J.

6. The method for recycling a solar panel according to claim 4, wherein:
the Vickers hardness of the processing media is 60 to 150 HV; and
the energy when colliding with the solar panel is 9.0×10⁻⁴ to 5.0×10⁻¹ J.

7. A device for recycling a solar panel comprising:
an impact force applying mechanism that applies an impact force to a solar panel by means of processing media;
an input portion that inputs a feature amount of the solar panel including a thickness of the cover glass and a hardness of the cover glass; and
a control portion that controls the impact force applying mechanism,
wherein the control portion sets a processing condition based on the feature amount of the solar panel and, based on the processing condition, controls an operation of the impact force applying mechanism to separate the cover glass covering a surface of the solar panel from the solar panel.

8. The device according to claim 7, wherein the impact force applying mechanism projects the processing media that is multiple particles having a diameter of 0.6 to 3.0 mm toward the solar panel.

9. The device according to claim 8 comprising:
a first separating mechanism that performs separation into broken pieces of the cover glass that was separated from the solar panel and the processing media, and the solar panel from which the cover glass was separated; and
a second separating mechanism that separates the broken pieces of the cover glass from the broken pieces of the cover glass and the processing media that were separated by the first separating mechanism.
